(19) United States
(12) Patent Application Publication
(10) Pub. No.: US 2024/0421117 A1
(43) Pub. Date: Dec. 19, 2024

(54) BONDING APPARATUS, BONDING METHOD AND ARTICLE MANUFACTURING METHOD

(71) Applicant: CANON KABUSHIKI KAISHA, Tokyo (JP)

(72) Inventor: KIYOTAKA NAKAMURA, Tochigi (JP)

(21) Appl. No.: 18/734,117

(22) Filed: Jun. 5, 2024

(30) Foreign Application Priority Data
Jun. 13, 2023 (JP) 2023-097244

(51) Int. Cl. H01L 23/00; H01L 21/66

(52) U.S. Cl. CPC H01L 24/74; H01L 22/20; H01L 24/80; H01L 2224/74; H01L 2224/80012; H01L 2224/80908

(57) ABSTRACT

A bonding apparatus including a head configured to bond a second object to a first object, a first camera configured to obtain an image by capturing the second object held by the head, and a control unit configured to determine a state of a bonding surface of the second object on a side of the first object based on an image obtained by the first camera in a state in which the second object is aligned with respect to the head, and control the head not to bond the second object held by the head to the first object if the state of the bonding surface is poor, and to bond the second object held by the head to the first object if the state of the bonding surface is excellent.

### BACKGROUND OF THE INVENTION

### Field of the Invention

The present invention relates to a bonding apparatus, a bonding method and an article manufacturing method.

### Description of the Related Art

For a bonding apparatus that bonds semiconductor wafers formed with a plurality of chips, Japanese Patent Laid-Open No. 2020-38946 proposes a technique of stacking (bonding) one semiconductor wafer while rotating it with respect to the other semiconductor wafer to maximize the number of non-defective chips. For the bonding apparatus, Japanese Patent Laid-Open No. 2010-274347 also proposes a technique of determining the quality (non-defective/defective) of a chip formed on a semiconductor wafer, and bonding, to a mounting substrate, only the chip determined to be a non-defective chip.

In the bonding apparatus, when bonding the chip by using an adhesive agent, it is unnecessary to remove the foreign particle which adheres to the chip during conveyance of the chip. On the other hand, when bonding the chip by hybrid bonding, since the foreign particle adhering to the bonding surface affects chip bonding, it is preferable to determine the state of the chip, that is, the quality of the chip immediately before bonding the chip.

However, the techniques proposed in Japanese Patent Laid-Open Nos. 2020-38946 and 2010-274347 are limited to determination of the quality of the chip on the semiconductor wafer, and cannot determine the chip which becomes a defective chip in a period from peeling of the chip from the semiconductor wafer to bonding thereof (for example, during conveyance of the chip).

### SUMMARY OF THE INVENTION

The present invention provides a bonding apparatus advantageous in bonding a second object to a first object.

According to one aspect of the present invention, there is provided a bonding apparatus that bonds a second object to a first object, including a head configured to hold the second object and bond the second object to the first object, a first camera configured to obtain an image by capturing the second object held by the head, and a control unit configured to determine a state of a bonding surface of the second object on a side of the first object based on an image obtained by the first camera in a state in which the second object is aligned with respect to the head, and control the head not to bond the second object held by the head to the first object if the state of the bonding surface is poor, and to bond the second object held by the head to the first object if the state of the bonding surface is excellent.

Further aspects of the present invention will become apparent from the following description of exemplary embodiments with reference to the attached drawings.

### BRIEF DESCRIPTION OF THE DRAWINGS

FIG. 1 is a view schematically showing the arrangement of a bonding apparatus as one aspect of the present invention.

FIG. 2 is a top view showing a substrate stage from the +Z direction.

FIG. 3 is a flowchart for explaining a bonding operation in the first embodiment.

FIG. 4 is a view schematically showing a state in which a bonding head holds a die.

FIG. 5 is a view for explaining a method of determining the state of the bonding surface of the die.

FIG. 6 is a view for explaining the method of determining the state of the bonding surface of the die.

FIG. 7 is a view schematically showing the arrangement of a bonding unit of a bonding apparatus as one aspect of the present invention.

FIG. 8 is a flowchart for explaining a bonding operation in the second embodiment.

FIG. 9 is a view schematically showing the arrangement of a bonding unit of a bonding apparatus as one aspect of the present invention.

FIG. 10 is a flowchart for explaining a bonding operation in the third embodiment.

FIG. 11 is a flowchart for explaining a bonding operation in the fourth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the following description, a substrate (wafer) with a semiconductor device formed thereon is defined as the first object (first bonding object), and a separated die including a semiconductor device is defined as the second object (second bonding object), but the present invention is not limited to this.

The first object includes, in addition to a substrate with a semiconductor device formed thereon, for example, a silicon substrate, a silicon substrate formed with wirings, a glass substrate, a glass panel formed with wirings, and an organic panel (PCB) formed with wirings. The first object also includes, for example, a metal panel, and a substrate with a semiconductor device formed thereon, to which some dies including semiconductor devices have already been bonded.

The second object includes, in addition to the separated die, for example, a stack of some already separated dies, a small piece of a material, an optical element, a MEMS, and a structure.

The bonding method of the first object and the second object is also not limited. The bonding method of the first object and the second object includes, for example, bonding using an adhesive agent, bonding using a temporary adhesive agent, bonding by hybrid bonding, atomic diffusion bonding, vacuum bonding, bump bonding, and the like. In this manner, the bonding method of the first object and the second object includes various temporary bonding methods and permanent bonding methods.

Industrial application examples of the bonding apparatus as one aspect of the present invention are, for example, application examples described below.

The first application example is manufacturing of a stacked memory. When the bonding apparatus as one aspect of the present invention is applied to manufacturing of a stacked memory, the first object is a substrate (wafer) with a memory as a semiconductor device manufactured thereon, and the second object is a memory as a separated die. In manufacturing of a stacked memory, in general, about eight layers are stacked. Hence, in bonding of the eighth layer, the first object is the substrate to which six layers of memories have already been bonded. The final layer may be a driver for driving the memories.

The second application example is heterogeneous integration of a processor. The mainstream of a conventional processor is an SoC obtained by forming a logic circuit and an SRAM in one semiconductor element. To the contrary, in heterogeneous integration, respective elements are manufactured on separate substrates while applying a process optimal for each element, and bonded to manufacture a processor. This can implement cost reduction and yield improvement of the processor. When the bonding apparatus as one aspect of the present invention is applied to heterogeneous integration, the first object is a substrate (wafer) with a logic device as a semiconductor device formed thereon. The second object is a die such as an SRAM, an antenna, or a driver separated after probing. Normally, different dies are sequentially bonded. Hence, the bonded objects on the first object sequentially increase. For example, in a case of starting bonding from an SRAM, when bonding the element next to the SRAM, the logic substrate (wafer) with the SRAM bonded thereto serves as the first object. Note that when bonding a plurality of dies, as for the order of bonding, bonding is preferably stated from a thin die such that a bonding head does not interfere with a bonded die.

The third application example is 2.5D bonding using a silicon interposer. The silicon interposer is a silicon substrate (wafer) with wirings formed thereon. The 2.5D bonding is a method of bonding separated dies using the silicon interposer, thereby electrically bonding the dies. When the bonding apparatus as one aspect of the present invention is applied to die bonding to the silicon interposer, the first object is a silicon substrate (wafer) formed with wirings, and the second object is a separated die. In general, a plurality of types of dies are bonded to the silicon interposer. Hence, the first object also includes a silicon interposer with several dies bonded thereto. When bonding a plurality of dies, as for the order of bonding, bonding is preferably started from a thin die such that a bonding head does not interfere with a bonded die.

The fourth application example is 2.1D bonding using an organic interposer or a glass interposer. The organic interposer is an organic panel (PCB substrate or CCL substrate) used as a package substrate, on which wirings are formed. The glass interposer is a glass panel with wirings formed thereon. The 2.1D bonding is a method of bonding separated dies to the organic interposer or the glass interposer, thereby electrically bonding the dies by the wirings on the interposer. When the bonding apparatus as one aspect of the present invention is applied to die bonding to the organic interposer, the first object is an organic panel formed with wirings, and the second object is a separated die. When the bonding apparatus as one aspect of the present invention is applied to die bonding to the glass interposer, the first object is a glass panel formed with wirings, and the second object is a separated die. In general, a plurality of types of dies are bonded to the organic interposer or the glass interposer. Hence, the first object also includes an organic interposer or a glass interposer with several dies bonded thereto. When bonding a plurality of dies, as for the order of bonding, bonding is preferably started from a thin die such that a bonding head does not interfere with a bonded die.

The fifth application example is temporary bonding in a fan-out package manufacturing process. There is known fan-out wafer-level packaging that reconstructs separated dies into a wafer shape using a mold resin to do packaging. There is also known fan-out panel-level packaging that reconstructs separated dies into a panel shape using a mold resin to do packaging. Such packaging is applied to semiconductor manufacturing as advanced packaging. In the packaging, rewirings from the dies to bumps are formed, or rewirings that bond different types of dies are formed on a molded reconstructed substrate. At this time, if the die array accuracy is low, when transferring the rewiring pattern using a step-and-repeat exposure apparatus, the rewiring pattern cannot accurately be positioned (aligned) with respect to the dies. For this reason, the dies are required to be arrayed with high accuracy. When the bonding apparatus as one aspect of the present invention is applied to the fan-out package manufacturing process, the first object is a metal panel, and the second object is a separated die. The separated dies are temporarily bonded to the substrate such as a metal panel by a temporary adhesive agent. After that, the separated dies are molded into a wafer shape or a panel shape by a molding apparatus, and separated from the metal panel after molding. Thus, a reconstructed wafer or a reconstructed panel is manufactured. In the application to this bonding, the bonding position by the bonding apparatus is preferably adjusted to correct an array deformation caused by the molding process.

The sixth application example is heterogeneous substrate bonding. For example, in the field of infrared image sensors, InGaAs is known as a high sensitivity material. Accordingly, if InGaAs is used for a sensor unit that receives light, and silicon capable of implementing high-speed processing is used for a logic circuit that extracts data, a high-sensitivity high-speed infrared image sensor can be manufactured. However, from InGaAs crystal, only substrates (wafers) whose diameter is as small as 4 inches are mass-produced, which is smaller than a mainstream silicon substrate having a size of 300 mm. Hence, a technique of bonding a separated InGaAs substrate to a 300-mm silicon substrate with a logic circuit formed thereon has been proposed. The bonding apparatus as one aspect of the present invention can also be applied to heterogeneous substrate bonding for bonding substrates made of different materials and having different sizes. When the bonding apparatus as one aspect of the present invention is applied to heterogeneous substrate bonding, the first object is a substrate such as a silicon substrate (wafer) with a large diameter, and the second object is a small piece of a material such as InGaAs. The small piece of the material is a slice of a crystal. The piece is preferably cut into a rectangular shape.

### First Embodiment

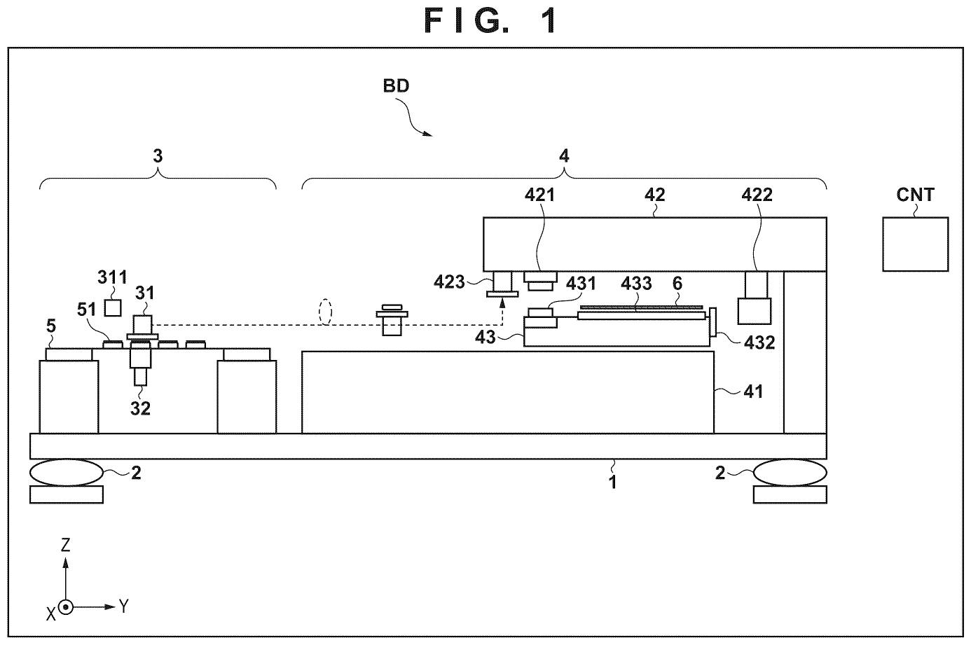

FIG. 1 is a view schematically showing the arrangement of a bonding apparatus BD as one aspect of the present invention. The bonding apparatus BD bonds a separated die 51 (second object) to an arbitrary position on a substrate 6 (first object) such as a wafer. The die 51 is provided while being arrayed (held) on a dicing tape put on a dicing frame 5. In this specification, as shown in respective drawings, directions are indicated on an XYZ coordinate system. Typically, an XY plane is a plane parallel to the horizontal plane, and a Z-axis is an axis parallel to the vertical direction. X-, Y-, and Z-axes are examples of directions that are orthogonal to each other or cross each other.

As shown in FIG. 1, the bonding apparatus BD includes a pickup unit 3 and a bonding unit 4, which are arranged on a base 1 damped by mounts 2. In this embodiment, the pickup unit 3 and the bonding unit 4 are arranged on one base 1. However, the pickup unit 3 and the bonding unit 4 may individually be arranged on separate bases.

The bonding apparatus BD further includes a control unit CNT formed by an information processing apparatus (computer) including a CPU, a memory, and the like. The control unit CNT operates the bonding apparatus BD by comprehensively controlling the respective units of the bonding apparatus BD, for example, the pickup unit 3 and the bonding unit 4, in accordance with a program stored in a memory unit.

The pickup unit 3 includes a pickup head 31, a release head 32, and a die observation camera 311. The pickup unit 3 peels the die 51 to be bonded to the substrate 6 from the dicing tape by the release head 32, and holds the die 51 peeled from the dicing tape by sucking (chucking) it with the pickup head 31. The pickup head 31 rotates the die 51 by, for example, 180° and passes it to a bonding head 423 of the bonding unit 4.

The pickup head 31 contacts the bonding surface of the die 51. Hence, in an application to a bonding method of performing bonding by activating the surface, like hybrid bonding, it is preferable to process the surface of the pickup head 31 that comes into contact with the bonding surface. For example, it is preferable to process the surface as a highly stable surface with a diamond like carbon (DLC) coating or a fluorine coating, or reduce the contact area by processing the surface into a small shape such as a pin shape with a high density.

The die observation camera 311 (second camera) is provided adjacent to the pickup head 31 above the dicing frame 5. The die observation camera 311 obtains an image by capturing the die 51 arrayed on the dicing tape. From the image obtained by the die observation camera 311, the control unit CNT obtains the position of the feature point (portion) of the die 51 arrayed on the dicing tape, the outer diameter dimension of the die 51, and the state of the bonding surface of the die 51. In this manner, the die observation camera 311 cooperates with the control unit CNT, thereby implementing a function of measuring the position of the feature point of the die 51, the outer diameter dimension of the die 51, and the state of the bonding surface of the die 51.

The bonding unit 4 includes a stage base 41 and an upper base 42. A substrate stage 43 is mounted on the stage base 41. The substrate stage 43 is configured to be capable of driving concerning the X direction and the Y direction by a driving mechanism (not shown) such as a linear motor. The substrate stage 43 may be configured to be capable of driving concerning a rotation about an axis parallel to the Z direction. Instead of driving the substrate stage 43 concerning the rotation about the axis parallel to the Z direction, the bonding head 423 may drive the die 51 concerning the rotation about the axis parallel to the Z direction.

A die observation camera 431 (first camera) is provided on the substrate stage 43. The die observation camera 431 obtains an image by capturing the die 51 held by the bonding head 423. From the image obtained by the die observation camera 431, the control unit CNT obtains the position of the feature point (portion) of the die 51 held by the bonding head 423, the outer diameter dimension of the die 51, and the state of the bonding surface of the die 51. In this manner, the die observation camera 431 cooperates with the control unit CNT, thereby implementing a function of measuring the position of the feature point of the die 51, the outer diameter dimension of the die 51, and the state of the bonding surface of the die 51. A bar mirror 432 is provided on the substrate stage 43. The bar mirror 432 is used as the target of an interferometer 422. The substrate stage 43 holds the substrate 6 via a substrate chuck 433.

A substrate observation camera 421 is provided on the upper base 42. The substrate observation camera 421 obtains an image by capturing the substrate 6 held by the substrate stage 43 (substrate chuck 433). From the image obtained by the substrate observation camera 421, the control unit CNT obtains the position of the feature point (portion) of the substrate 6 and the state of the bonding surface of the substrate 6 held by the substrate stage 43. In this manner, the substrate observation camera 421 cooperates with the control unit CNT, thereby implementing a function of measuring the position of the feature point (portion) of the substrate 6 and the state of the bonding surface of the substrate 6. The substrate observation camera 421 may be a camera capable of measuring an element pattern or mark formed on the substrate or inside the substrate by using infrared light as measurement light.

The upper base 42 is further provided with the interferometer 422 for measuring the position of the substrate stage 43 using the bar mirror 432, and the bonding head 423 for holding the die 51 passed from the pickup head 31.

When bonding the die 51 to the substrate 6 (bonding target portion thereof), for example, the bonding head 423 is driven downward (−Z direction) to bond the die 51 held by the bonding head 423 to the substrate 6 held by the substrate stage 43. Alternatively, the substrate stage 43 or the substrate chuck 433 may be driven upward (+Z direction) to bond the die 51 held by the bonding head 423 to the substrate 6 held by the substrate stage 43.

In this embodiment, the configuration is employed in which the pickup head 31 rotates the die 51 by 180° and passes it to the bonding head 423. However, by providing one or more die holding units between the pickup head 31 and the bonding head 423, the pickup head 31 may pass the die 51 to the die holding unit, and the die holding unit may pass the die 51 to the bonding head 423. Alternatively, a driving mechanism that drives the bonding head 423 may be provided and drive the bonding head 423 such that the bonding head 423 receives the die 51 from the pickup head 31. Note that, in order to improve productivity, the bonding apparatus BD may include a plurality of pickup heads, a plurality of release heads, and a plurality of bonding heads.

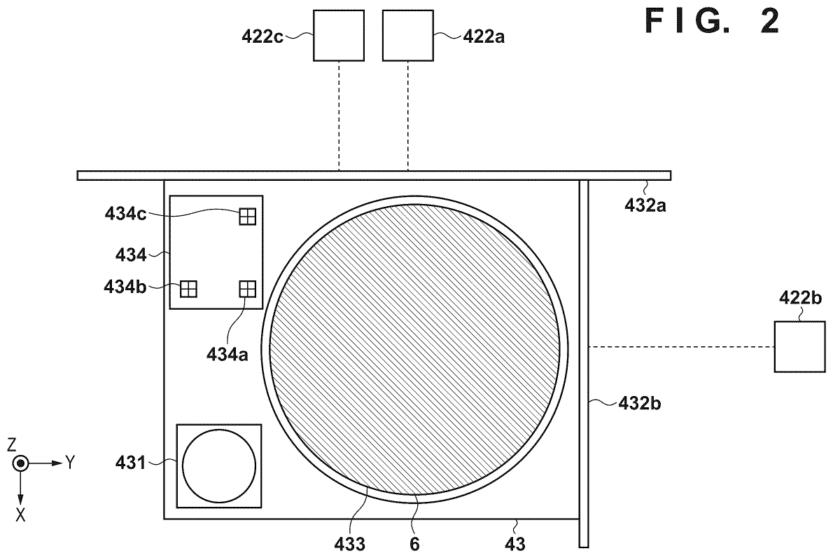

FIG. 2 is a top view showing the substrate stage 43 from the +Z direction. The substrate 6 is held by the substrate stage 43 via the substrate chuck 433. The substrate 6 or the substrate stage 43 is positioned concerning the X direction and the Y direction, which are orthogonal to each other or cross each other, and the rotation about the axis parallel to the Z direction orthogonal to the X and Y directions. For this purpose, the substrate stage 43 is provided with the bar mirror 432, more specifically, bar mirrors 432a and 432b. The bar mirror 432a is used as the target of interferometers 422a and 422c. The control unit CNT can obtain the position of the substrate stage 43 in the X direction based on the output from the interferometer 422a, and obtain the rotation (rotation amount) of the substrate stage 43 about the axis parallel to the Z direction based on the outputs from the interferometers 422a and 422c. The bar mirror 432b is used as the target of an interferometer 422b. The control unit CNT can obtain the position of the substrate stage 43 in the Y direction based on the output from the interferometer 422b. Based on the outputs from the interferometers 422a, 422b, and 422c, the control unit CNT feedback-controls the substrate 6 or the substrate stage 43 concerning the X direction, the Y direction, and the rotation about the axis parallel to the Z direction orthogonal to the X and Y directions. In this manner, the interferometer 422 and the control unit CNT function as a positioning mechanism that positions the substrate 6 or the substrate stage 43.

A reference plate 434 is provided on the substrate stage 43 (upper surface thereof). In this embodiment, a plurality of marks 434a, 434b, and 434c are arranged (drawn) on the reference plate 434. The reference plate 434 is made of a material with a low thermal expansion coefficient, and the marks 434a, 434b, and 434c are drawn at a high position accuracy. For an example, the reference plate 434 is formed by a quartz substrate, and the marks 434a, 434b, and 434c are drawn thereon using the drawing method of a semiconductor lithography process. The reference plate 434 has a surface with almost the same height as the surface of the substrate 6, and can be observed by the substrate observation camera 421. A camera used to observe the reference plate 434 may separately be provided.

The substrate stage 43 may have a configuration that combines a coarse motion stage that is driven within a large range, and a fine motion stage that is accurately driven within a small range. In this configuration, the die observation camera 431, the bar mirrors 432a and 432b, the substrate chuck 433, and the reference plate 434 are provided on the fine motion stage to implement accurate positioning.

A method of guaranteeing the origin position, the magnification, and the directions (rotations) and orthogonality of the X-axis and the Y-axis of the substrate stage 43 using the reference plate 434 will be described here. The mark 434a is observed by the substrate observation camera 421, and the measured value (output value) of the interferometer when the mark 434a is located at the center of the image obtained by the substrate observation camera 421 is defined as the origin of the substrate stage 43. Next, the mark 434b is observed by the substrate observation camera 421, and the direction (rotation) of the Y-axis of the substrate stage 43 and the magnification in the Y direction are decided based on the measured value of the interferometer when the mark 434b is located at the center of the image obtained by the substrate observation camera 421. Next, the mark 434c is observed by the substrate observation camera 421, and the direction (rotation) of the X-axis of the substrate stage 43 and the magnification in the X direction are decided based on the measured value of the interferometer when the mark 434c is located at the center of the image obtained by the substrate observation camera 421.

In this manner, defining the direction from the mark 434b of the reference plate 434 to the mark 434a as the Y-axis of the bonding apparatus BD, and the direction from the mark 434c to the mark 434a as the X-axis of the bonding apparatus BD, the directions and orthogonality of the axes can be calibrated. Also, defining the interval between the mark 434b and the mark 434a as the scale reference of the Y-axis of the bonding apparatus BD and the interval between the mark 434c and the mark 434a as the scale reference of the X-axis of the bonding apparatus BD, calibration can be performed.

In the interferometer, the refractive index of the optical path changes due to variations of the atmospheric pressure and temperature, and this makes the measured value vary. Therefore, it is preferable to perform calibration at an arbitrary timing and guarantee the origin position, the magnification, and the directions (rotations) and orthogonality of the X-axis and the Y-axis of the substrate stage 43. To reduce the variation of the measured value of the interferometer, the space in which the substrate stage 43 is arranged may be covered with a temperature control chamber to control the temperature in the temperature control chamber.

In this embodiment, a case where the reference plate 434 provided on the substrate stage 43 is observed by the substrate observation camera 421 has been described, but the present invention is not limited thereto. For example, by providing the reference plate 434 on the upper base 42, and observing the reference plate 434 provided on the upper base 42 by the die observation camera 431, the origin position, the magnification, the directions (rotations) and orthogonality of the X-axis and the Y-axis of the substrate stage 43 may be guaranteed. Instead of performing calibration by observing the reference plate 434, for example, calibration may be performed by an abutting operation to a reference surface, or accurate positioning may be performed using a position measurement device such as a white interferometer that guarantees an absolute value.

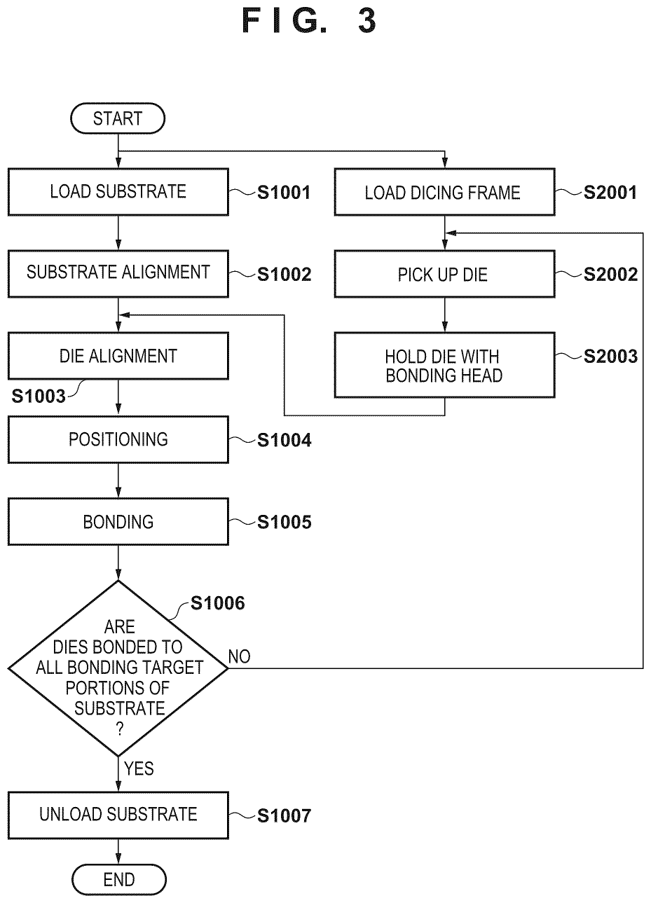

With reference to FIG. 3, an operation of the bonding apparatus BD in the first embodiment, that is, a bonding operation (bonding method) of bonding the die 51 to the substrate 6 will be described. As has been described above, the bonding operation is performed by the control unit CNT comprehensively controlling the respective units of the bonding apparatus BD.

In step S1001, the substrate 6 is loaded into the bonding apparatus BD, and the substrate stage 43 (substrate chuck 433) holds the substrate 6. Since adhesion of a foreign particle to the bonding surface of the substrate 6 (and the bonding surface of the die 51) causes a bonding failure, the interior (space) of the bonding apparatus BD is kept at a high cleanliness of, for example, class 1. Further, to keep a high cleanliness, the substrate 6 is stored in a container such as a FOUP that has a high airtightness and maintains a high cleanliness and loaded from the container into the bonding apparatus BD. To increase the cleanliness, the substrate 6 may be washed in the bonding apparatus BD after loading the substrate 6 into the bonding apparatus BD. Preprocessing for bonding is also executed for the substrate 6 loaded into the bonding apparatus BD. For example, in a case of bonding the substrate 6 and the die 51 using an adhesive agent, processing of applying the adhesive agent to the substrate 6 is executed. In a case of bonding the substrate 6 and the die 51 by hybrid bonding, processing of activating the bonding surface (surface) of the substrate 6 is executed. The substrate 6 undergoes coarse alignment by a prealigner based on a notch or an orientation flat and the outer shape position of the substrate 6, and held by the substrate stage 43 via the substrate chuck 433.

In step S1002, substrate alignment is performed. More specifically, the substrate observation camera 421 obtains an image by capturing the substrate 6 held by the substrate stage 43, and the position of the feature point of the substrate 6 is obtained based on the image to decide the position of the bonding surface of the substrate 6. Note that the positional relationship (relative position) between the feature point of the substrate 6 and the bonding surface of the substrate 6 is known. Focus adjustment performed to capture the substrate 6 by the substrate observation camera 421 is implemented by, for example, a focus adjustment mechanism included in the substrate observation camera 421. Alternatively, focus adjustment performed to capture the substrate 6 by the substrate observation camera 421 may be implemented by driving the substrate stage 43 (substrate 6 held thereby) in the Z direction. In many cases, an alignment mark is formed on the substrate 6. If no alignment mark is formed, a feature point that can specify the position of the substrate 6 may be measured. For example, the control unit CNT obtains, as the position of the feature point of the substrate 6, the relative position of the feature point (image thereof) of the substrate 6 with respect to the center of the image obtained by the substrate observation camera 421.

To accurately measure the relative position of a mark with respect to the reference point of the bonding apparatus BD, an offset amount may be obtained in advance. More specifically, the substrate stage 43 is driven such that the mark of the reference plate 434 falls within the visual field of the substrate observation camera 421, and the position of the mark is measured by the substrate observation camera 421. Based on the position of the substrate stage 43 at that time and the position of the mark measured using the substrate observation camera 421, the offset amount with respect to the position of the mark measured by the substrate observation camera 421 is decided. Note that, in general, the reference point of the bonding apparatus BD is often a specific mark position of the reference plate 434. However, another position (for example, the origin position of the substrate stage 43) may be set if it is a position serving as a reference.

Since the measurement range of a rotation direction by the interferometer 422 is narrow, a rotation amount that can be corrected by the substrate stage 43 is small. Therefore, if the rotation amount of the substrate 6 is large, it is preferable to detach the substrate 6 from the substrate stage 43, correct the rotation of the substrate 6, and then hold the substrate 6 again by the substrate stage 43. If the substrate 6 is held again by the substrate stage 43, substrate alignment needs to be performed again. Note that, for substrate alignment, the position (so-called surface position) of the bonding surface of the substrate 6 in the height direction (Z direction) may be measured during focus adjustment or using a height measurement device (not shown). Since the thickness of the substrate 6 varies, measuring the surface position of the substrate 6 is advantageous in accurately managing (controlling) the gap between the substrate 6 and the die 51 in the bonding operation.

Since the origin position, the magnification, and the directions (rotations) and orthogonality of the X-axis and the Y-axis of the substrate stage 43 are guaranteed using the reference plate 434, the position of the feature point of the substrate 6 is measured based on the origin position and the X- and Y-axes of the substrate stage 43. On the substrate 6, semiconductor devices serving as bonding target portions are formed at a predetermined period. These semiconductor devices are formed by accurately positioning a plurality of layers in a semiconductor manufacturing apparatus. Hence, the semiconductor devices are repetitively arrayed generally at a period with a nano-level accuracy. Therefore, in substrate alignment, it is not necessary to measure the positions of feature points corresponding to all the bonding target portions (semiconductor devices) of the substrate 6. For example, the control unit CNT may measure the positions of measurement target portions in number smaller than the number of bonding target portions of the substrate 6 and statistically process the measurement result, thereby deciding the positions of a plurality of bonding target portions of the substrate 6. The plurality of measurement target portions of the substrate 6 can be decided based on the array information of semiconductor devices. To decide the positions of the plurality of bonding target portions of the substrate 6, the control unit CNT can calculate the origin position of the repetitive array of the bonding target portions, the rotation amounts and orthogonality of the directions of the X-axis and the Y-axis, and the magnification error of the repetitive period based on the measurement result of the positions of measurement target portions.

In addition, the substrate stage 43 (substrate chuck 433) preferably has a temperature control function of controlling the temperature of the substrate 6. This is because, in a case of a silicon wafer having a thermal expansion coefficient of 3 ppm/° C. and a diameter of 300 mm, if the temperature increases by 1° C., the position of the outermost periphery is displaced by 150 mm×0.000003=0.00045 mm=450 nm. If the bonding target portion of the substrate 6 is displaced after substrate alignment, bonding cannot be performed at a high position accuracy. It is therefore preferable to stabilize the temperature of the substrate 6 held by the substrate stage 43 at an accuracy of 0.1° C. or less.

If the substrate 6 is an interposer on which wirings are formed, the bonding target portions of the substrate 6 are decided based on not the array of semiconductor devices but the array of the repetitively formed wirings. If the substrate 6 is a wafer or panel without a pattern, substrate alignment is not executed.

The processing concerning the die 51, which is executed in parallel to or after the loading of the substrate 6 (step S1001) and substrate alignment (step S1002) will be described below.

In step S2001, the dicing frame 5 on which the dies 51 separated by a dicer are arrayed on a dicing tape is loaded into the bonding apparatus BD. In general, the dicing frame 5 is conveyed by an unsealed magazine. However, since adhesion of a foreign particle to the bonding surface of the die 51 causes a bonding failure, the dicing frame 5 is preferably conveyed using a container that has a high airtightness and maintains a high cleanliness. Further, to increase the cleanliness, the dies 51 arrayed on the dicing tape put on the dicing frame 5 may be washed in the bonding apparatus BD. The rotation direction and the shift position of the dicing frame 5 are coarsely decided by a prealigner (not shown) based on the outer shape of the dicing frame 5.

In step S2002, the die 51 is picked up from the dicing frame 5 (dicing tape) by the pickup head 31 and the release head 32. More specifically, the pickup head 31 and the release head 32 are positioned such that the die 51 to be picked up is located (sandwiched) between the pickup head 31 and the release head 32. The release head 32 peels, from the dicing frame, the die 51 to be picked up while the die 51 is sucked by the pickup head 31. Thus, the die 51 is held by the pickup head 31. The die 51 to be picked up is decided based on, for example, non-defective die (KGD: Known Good Die) information transmitted to the bonding apparatus BD online. Normally, only non-defective dies are picked up. However, when bonding a defective die (KBD: Known Bad Die) to the defective bonding target portion (defective semiconductor device) of the substrate 6, a defective die is picked up.

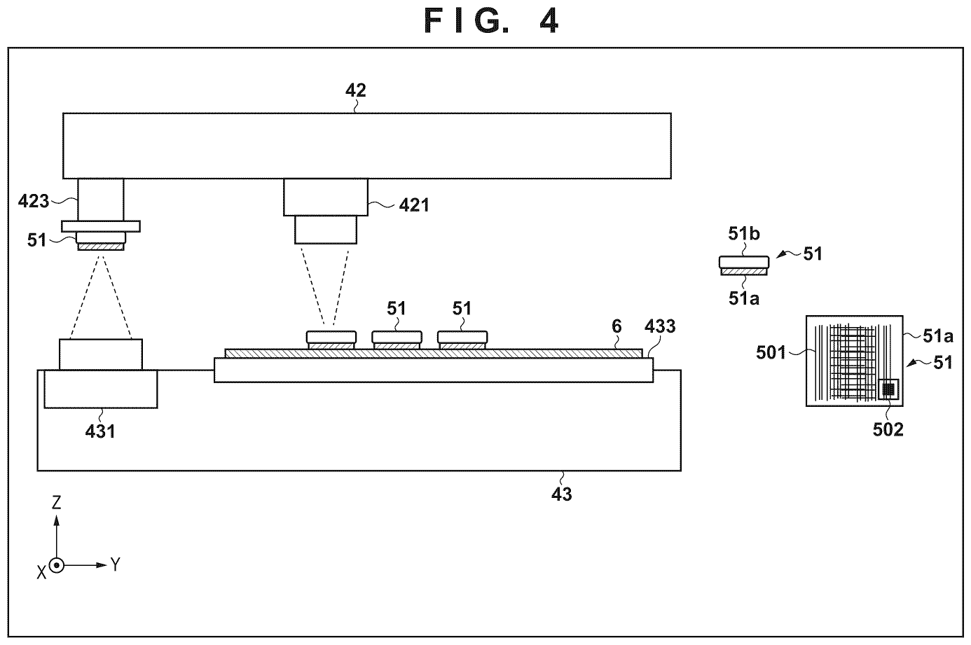

In step S2003, the die 51 held by the pickup head 31 is transferred (conveyed) to the bonding head 423, and the bonding head 423 holds the die 51. FIG. 4 is a view schematically showing a state in which the bonding head 423 holds the die 51. When the die 51 is picked up by the pickup head 31, a bonding surface 51a of the die 51 faces the pickup head 31. On the other hand, the die 51 is conveyed to the bonding head 423 such that a non-bonding surface 51b on the opposite side of the bonding surface 51a of the substrate 6 faces the bonding head 423. Hence, as shown in FIG. 4, the bonding head 423 chucks the non-bonding surface 51b, thereby holding the die 51 with the bonding surface 51a facing the substrate 6. Note that an element pattern 501 and an alignment mark 502 are formed on the bonding surface 51a of the die 51.

The transfer of the die 51 to the bonding head 423 may be done directly by the pickup head 31 to the bonding head 423 or may be done via a die holding unit. During the conveyance of the die 51, preprocessing for bonding of the substrate 6 and the die 51 may be executed for the die 51 (bonding surface 51a thereof). The preprocessing includes, for example, processing of washing the die 51 (bonding surface 51a thereof), processing of applying an adhesive agent in a case of bonding using an adhesive agent, or processing of activating the bonding surface 51a of the die 51 in a case of hybrid bonding.

With the processing operations in steps S1001, S1002, S2001, S2002, and S2003, a state in which the substrate 6 is held by the substrate stage 43 (substrate chuck 433) and the die 51 is held by the bonding head 423 as shown in FIG. 4 is obtained.

In step S1003, die alignment is performed. First, the position of the die 51 held by the bonding head 423 is measured. More specifically, the substrate stage 43 is driven to make the feature point of the die 51, for example, the element pattern 501 or the alignment mark 502 on the bonding surface 51a of the die 51 fall within the visual field of the die observation camera 431. Focus adjustment performed to capture the die 51 by the die observation camera 431 may be implemented by a focus adjustment mechanism included in the die observation camera 431, or may be implemented by driving the substrate stage 43 (die observation camera 431) in the Z direction. Note that, since a scribe line formed with an alignment mark used for alignment in a semiconductor manufacturing step is removed by dicing, the die 51 may not include the alignment mark 502. In this case, a terminal portion of an array of pads or bumps arranged on the die 51, or the region or outer shape that can specify the position of the die 51 in an aperiodic array may be defined as a feature point to measure the position of the die 51.

The control unit CNT obtains, as the position of the feature point of the die 51, the relative position of the feature point (image thereof) of the die 51 with respect to the center of the image obtained by capturing, by the die observation camera 431, the die 51 held by the bonding head 423. When measuring the position of the die 51, it is preferable to measure the positions of a plurality of feature points of the die 51 and measure the rotation (rotation amount) of the die 51 as well. To measure the positions of the plurality of feature points of the die 51, the substrate stage 43 may be driven every time the position of each feature point is measured, or the visual field of the die observation camera 431 may be designed to observe the plurality of feature points at once.

The rotation of the die 51 can be corrected by rotating the substrate stage 43 at the time of bonding the die 51 to the substrate 6. However, as has been described above, since the measurement range of a rotation direction by the interferometer 422 is narrow, a rotation amount that can be corrected by the substrate stage 43 is small. Therefore, if the rotation amount of the die 51 is large, it is preferable to detach the die 51 from the bonding head 423, correct the rotation of the die 51, and then hold the die 51 again by the bonding head 423. If the die 51 is held again by the bonding head 423, die alignment needs to be performed again.

Note that, for die alignment, the position (so-called surface position) of the bonding surface 51a of the die 51 in the height direction (Z direction) may be measured during focus adjustment or using a height measurement device (not shown). Since the thickness of the die 51 varies, measuring the surface position of the die 51 is advantageous in accurately managing (controlling) the gap between the substrate 6 and the die 51 in the bonding operation.

Also, heights at a plurality of positions on the die 51 may be measured, and the posture of the die 51 or the substrate 6 may be adjusted by a tilt mechanism (not shown) at the time of bonding the die 51 to the substrate 6. This tilt mechanism is incorporated in, for example, the substrate stage 43, the substrate chuck 433, or the bonding head 423.

In die alignment, based on the position of the feature point of the die 51, the outer shape of the die 51 and the position of the feature point (for example, the element pattern 501 or the alignment mark 502) of the die 51 are associated. Positional information including information indicating the relative positional relationship between the outer shape of the die 51 and the feature point associated as described above is stored in a storage unit (not shown) of the bonding apparatus BD. Note that the positional information may be input from the outside of the bonding apparatus BD to the storage unit of the bonding apparatus BD.

Further, in die alignment, the control unit CNT determines, based on the image obtained by the die observation camera 431, the state (quality) of the bonding surface 51a of the die 51 held by the bonding head 423. Here, the state of the bonding surface 51a of the die 51 means the state regarding the quality of the bonding surface 51a of the die 51. The state of the bonding surface 51a of the die 51 includes, for example, the presence/absence of chipping of the outer shape of the bonding surface 51a, the presence/absence of a positional deviation of the element pattern 501 formed in the bonding surface 51a, the presence/absence of chipping of the element pattern 501 formed in the bonding surface 51a, the presence/absence of adhesion of a foreign particle to the bonding surface 51a, and the like.

For example, consider hybrid bonding. If a foreign particle adheres to the bonding surface 51a during conveyance of the die 51 from the dicing frame 5 to the bonding head 423, the bonding strength of the die 51 with respect to the substrate 6 can decrease. Therefore, it is important to determine the state of the bonding surface 51a of the die 51 held by the bonding head 423 before (immediately before) bonding the die 51 to the substrate 6.

To implement this, in this embodiment, before (immediately before) bonding the die 51 to the substrate 6, the state of the bonding surface 51a is determined based on the image obtained by capturing the die 51 (bonding surface 51a thereof) held by the bonding head 423 by the die observation camera 431. For example, the state of the bonding surface 51a of the die 51 can be determined by comparing the image obtained by the die observation camera 311 with the image obtained by the die observation camera 431. Here, the image obtained by the die observation camera 311 corresponds to the image of the die 51 obtained before the die 51 is picked up from the dicing tape, that is, before the die 51 is held by the bonding head 423.

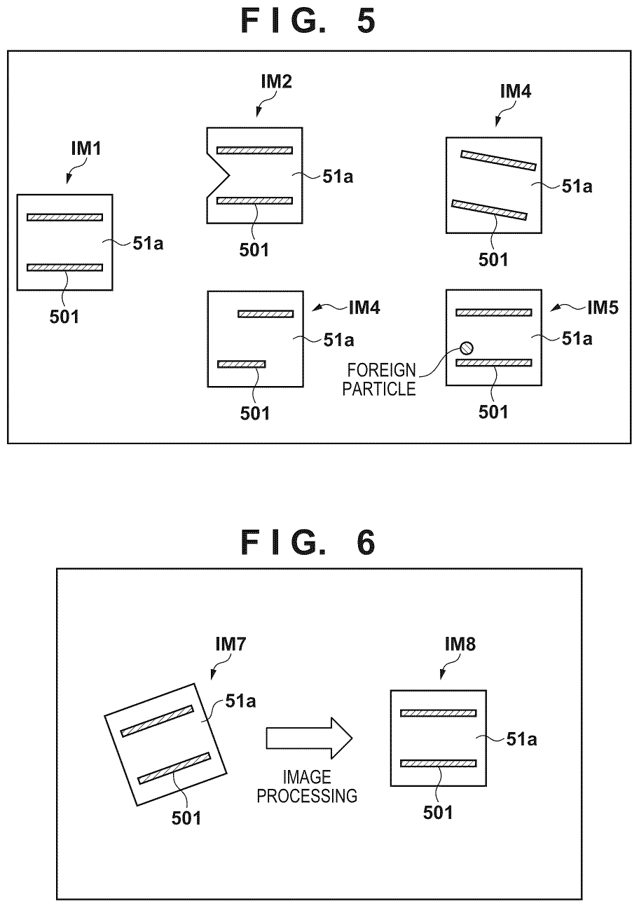

More specifically, an image IM2, IM3, IM4, or IM5 obtained by the die observation camera 431 is compared with an image IM1 obtained by the die observation camera 311. With this, in a case of comparison between the image IM1 and the image IM2, chipping of the outer shape of the bonding surface 51a is detected. In a case of comparison between the image IM1 and the image IM3, the positional deviation of the element pattern 501 formed in the bonding surface 51a is detected. In a case of comparison between the image IM1 and the image IM4, chipping of the element pattern 501 formed in the bonding surface 51a is detected, and in a case of comparison between the image IM1 and the image IM5, adhesion of a foreign particle to the bonding surface 51a is detected. If the state as described above is detected, it is determined that the state of the bonding surface 51a of the die 51 is poor. If the state as described above is not detected, it is determined that the state of the bonding surface 51a of the die 51 is excellent. Note that the state of the bonding surface 51a of the die 51 can be determined using, instead of the image IM1 obtained by the die observation camera 311, a reference image obtained by capturing the die 51 with the bonding surface 51a in an excellent state. FIG. 5 is a view for explaining a method of determining the state of the bonding surface 51a of the die 51 held by the bonding head 423.

In this embodiment, a description has been given assuming that the image of the die 51 (bonding surface 51a thereof) used to determine the state of the bonding surface 51a of the die 51 is an image obtained by the die observation camera 431 when the die 51 is aligned with respect to the bonding head 423. However, in practice, when obtaining the image by the die observation camera 431, the die 51 is not necessarily aligned with respect to the bonding head 423. If the die 51 is not aligned with respect to the bonding head 423, it is necessary to perform image processing of an image IM7 obtained by the die observation camera 431, as shown in FIG. 6. More specifically, from the image IM7 obtained by the die observation camera 431, the alignment amount required for alignment of the die 51 with respect to the bonding head 423 is obtained, and image processing of the image IM7 is performed based on the obtained alignment amount. Then, based on an image IM8 as the image processing result of the image IM7 obtained by the die observation camera 431, the state of the bonding surface 51a of the die 51 is determined. FIG. 6 is a view for explaining the method of determining the state of the bonding surface 51a of the die 51 held by the bonding head 423.

Referring back to FIG. 3, in step S1004, positioning for bonding the die 51 to the substrate 6 is performed. More specifically, the substrate stage 43 is driven to position the die 51 with respect to the bonding target portion of the substrate 6. At this time, the control unit CNT feedback-controls the substrate stage 43 (position thereof) based on the measured result of the interferometer 422. In addition, the target position of the substrate stage 43 is determined while reflecting the position and rotation amount of the substrate 6 and the position and rotation amount of the die 51 obtained in steps S1002 and S1003. Further, if a shift occurs due to the bonding operation of bonding the die 51 to the substrate 6, the target position of the substrate stage 43 is determined while taking the shift into consideration as an offset amount.

In step S1005, the die 51 held by the bonding head 423 is bonded to the substrate 6 held by the substrate stage 43 (substrate chuck 433). In this embodiment, if it is determined in die alignment (step S1003) that the state of the bonding surface 51a is excellent, the die 51 held by the bonding head 423 is bonded to the substrate 6. On the other hand, if it is determined in die alignment (step S1003) that the state of the bonding surface 51a is poor, the die 51 held by the bonding head 423 is not bonded to the substrate 6.

As an operation for bonding the die 51 to the substrate 6, the bonding head 423 may be lifted/lowered, or the substrate stage 43 (substrate chuck 433) may be lifted/lowered. To suppress deterioration of the positioning accuracy at the time of lifting/lowering the bonding head 423 or the substrate stage 43, a lifting driving system with high reproducibility is preferably employed for the bonding head 423 or the substrate stage 43. In a case of lifting/lowering the substrate stage 43 while continuing feedback control, the width of the bar mirror 432 in the Z direction is designed such that the bar mirror 432 does not deviate from the optical path of the interferometer 422. On the other hand, in a case of lifting/lowering the bonding head 423, feedback control is performed while monitoring the position deviations of the bonding head 423 in the X and Y directions using an encoder or a gap sensor. To accurately control the gap between the substrate 6 and the die 51, a linear encoder may be provided to measure the z-axis direction position of the lifting driving mechanism. If the substrate 6 and the die 51 come into contact with each other, the substrate stage 43 that is feedback-controlled using the interferometer 422 is restrained. Hence, the control method may be changed before and after contact by, for example, stopping feedback control. Processing until bringing the die 51 into contact with the bonding target portion of the substrate 6 has been described above. In bump bonding, a step necessary for bonding, such as a step of pressing the die 51 against the substrate 6 at a predetermined pressing pressure is added. After bonding the die 51 to the substrate 6, a step of observing the bonding state between the die 51 and the substrate 6 may also be added.

In step S1006, it is determined whether the dies 51 are bonded to all the bonding target portions of the substrate 6. In general, several tens to several hundreds of bonding target portions (semiconductor devices) exist on one substrate 6. Since the die 51 is bonded to each of the bonding target portions, bonding of the die 51 to the substrate 6 is repeated a plurality of times. If bonding of the dies 51 to all the bonding target portions of the substrate 6 is not ended, the process returns to step S2002 to bond the die 51 to the next bonding target portion of the substrate 6. Note that in this embodiment, after bonding (step S1005), it is determined whether the dies 51 are bonded to all the bonding target portions of the substrate 6, and pickup of the die 51 is performed (step S2002). However, pickup of the die 51 (step S2002) may be executed in parallel between die alignment (step S1003) and bonding (step S1005). When bonding a plurality of types of dies to one bonding target portion (semiconductor device), after bonding of dies of one type to all the bonding target portions of one substrate 6 is ended, bonding of dies of the next type is started. In this case, in step S2002, a die of the next type is picked up. At this time, necessary processing such as an operation of loading a dicing frame corresponding to dies of the next type is executed.

If bonding of the dies 51 to all the bonding target portions of the substrate 6 is ended, the process transitions to step S1007. In step S1007, the substrate 6 with the dies 51 bonded thereto is unloaded from the bonding apparatus BD. The substrate 6 may be returned to the FOUP, or may be returned to another container. In general, however, the thickness of the substrate 6 changes due to bonding of the dies 51. Therefore, when storing the substrate 6, the gap between substrates needs to be extended as compared to substrates before bonding, so that the substrate 6 is returned to another container.

In this embodiment, the bonding operation of bonding the plurality of dies 51 to one substrate 6 has been described, but the bonding operation is repeated for a necessary number of the substrates 6. Note that since the number of dies 51 arrayed on the dicing tape put on the dicing frame 5 and the number of bonding target portions (semiconductor devices) of the substrate 6 are generally different, loading of the substrate 6 and the loading of the dicing frame 5 do not synchronize. If the dies 51 on the dicing frame 5 run out during bonding of the dies 51 to one substrate 6, the new dicing frame 5 is loaded. If the dies 51 on the dicing frame 5 remain even after the end of bonding of the dies 51 to all the bonding target portions of one substrate 6, those dies 51 are used for bonding to the next substrate 6.

In this manner, according to this embodiment, it is possible to determine the state (quality thereof) of the bonding surface 51a of the die 51 immediately before bonding the die 51 to the substrate 6. For example, it is possible to determine the die 51 that becomes defective during conveyance of the die 51 from the dicing frame 5 to the bonding head 423. Hence, in this embodiment, it is possible to provide the bonding apparatus BD advantageous in bonding the die 51 to the substrate 6.

### Second Embodiment

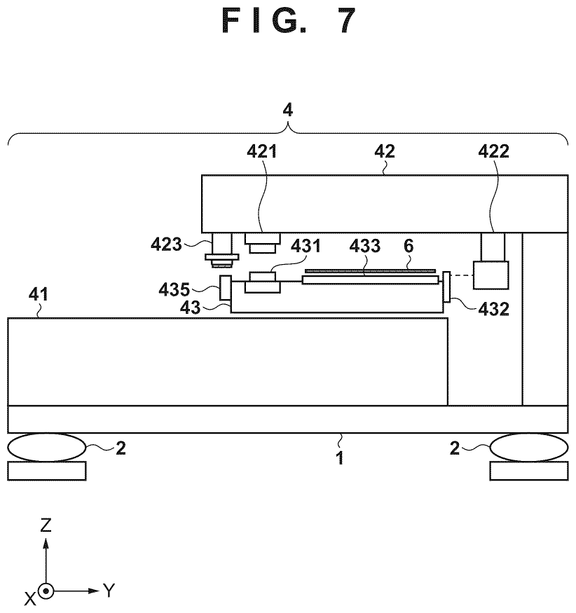

If there is a foreign particle adhering to a bonding surface 51a of a die 51 held by a bonding head 423, cleaning for removing the foreign particle adhering to the bonding surface 51a of the die 51 is preferably performed in a bonding apparatus BD. Therefore, as shown in FIG. 7, the bonding apparatus BD may be provided with a cleaning unit 435 that performs cleaning for removing a foreign particle adhering to the bonding surface 51a of the die 51 held by the bonding head 423. FIG. 7 is a view schematically showing the arrangement of a bonding unit 4 of the bonding apparatus BD.

In the bonding unit 4, the cleaning unit 435 is provided on a substrate stage 43, for example, so as to face the die 51 (bonding surface 51a thereof) held by the bonding head 423. In this embodiment, the cleaning unit 435 removes a foreign particle adhering to the bonding surface 51a of the die 51 by blowing air (that is, by air blow) to the bonding surface 51a of the die 51 held by the bonding head 423. Accordingly, the cleaning unit 435 only needs to be arranged at a position where it can blow out the foreign particle adhering to the bonding surface 51a of the die 51 held by the bonding head 423, and may be arranged on, for example, a stage base 41 or an upper base 42. Note that, when providing the cleaning unit 435 in the bonding apparatus BD, it is preferable to also provide a mechanism (for example, a vacuum mechanism) that discharges, from the bonding apparatus BD, the foreign particle blown out from the bonding surface 51a of the die 51 by the cleaning unit 435.

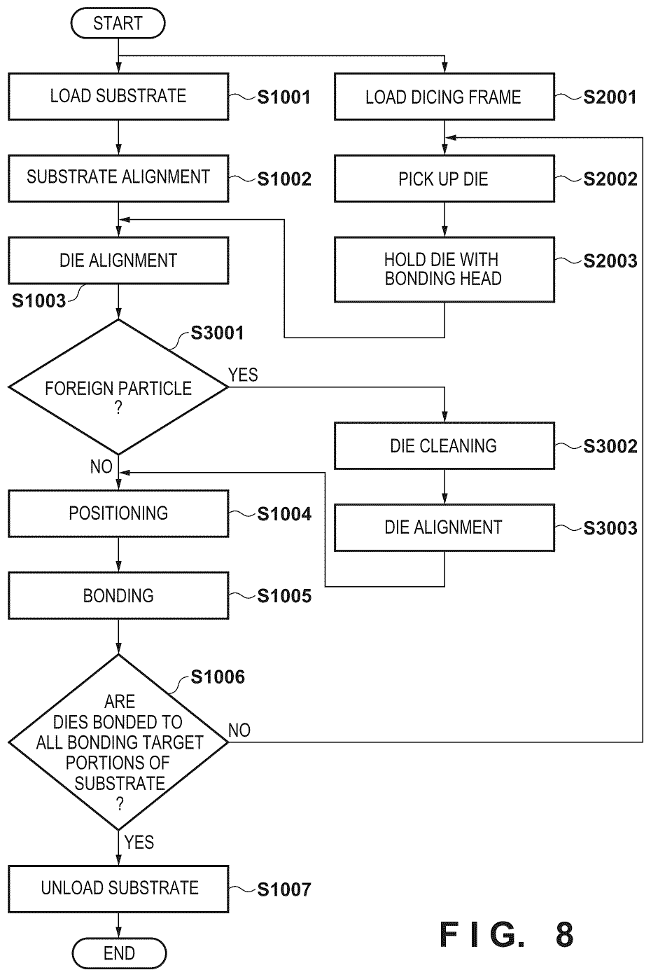

With reference to FIG. 8, an operation of the bonding apparatus BD in the second embodiment, that is, a bonding operation (bonding method) of bonding the die 51 to a substrate 6 will be described. As has been described above, the bonding operation is performed by a control unit CNT comprehensively controlling the respective units of the bonding apparatus BD. The bonding operation in this embodiment is different from the bonding operation (FIG. 3) in the first embodiment in that processing operations in steps S3001, S3002, and S3003 are included between die alignment (step S1003) and positioning (step S1004).

In step S3001, based on the determination (result) of the state of the bonding surface 51a of the die 51 in die alignment (step S1003), it is determined whether there is a foreign particle adhering to the bonding surface 51a of the die 51. If it is determined that there is no foreign particle adhering to the bonding surface 51a of the die 51, the process transitions to step S1004. On the other hand, if there is a foreign particle adhering to the bonding surface 51a of the die 51, the process transitions to step S3002.

In step S3002, cleaning of the bonding surface 51a of the die 51 held by the bonding head 423 is performed. More specifically, as shown in FIG. 7, the substrate stage 43 is driven such that the cleaning unit 435 faces the bonding surface 51a of the die 51 held by the bonding head 423. Then, air is blown from the cleaning unit 435 to the bonding surface 51a of the die 51, thereby removing the foreign particle adhering to the bonding surface 51a of the die 51. Note that the foreign particle blown out from the bonding surface 51a of the die 51 by the cleaning unit 435 is preferably discharged from the bonding apparatus BD by the vacuum mechanism.

In step S3003, to determine (check) the state of the bonding surface 51a of the die 51 with the foreign particle removed by the cleaning unit 435, die alignment is performed as in step S1003.

In this manner, according to this embodiment, it is possible to set the excellent state of the bonding surface 51a by removing a foreign particle adhering to the bonding surface 51a of the die 51, if any, immediately before bonding the die 51 to the substrate 6. Hence, in this embodiment, it is possible to provide the bonding apparatus BD advantageous in bonding the die 51 to the substrate 6.

### Third Embodiment

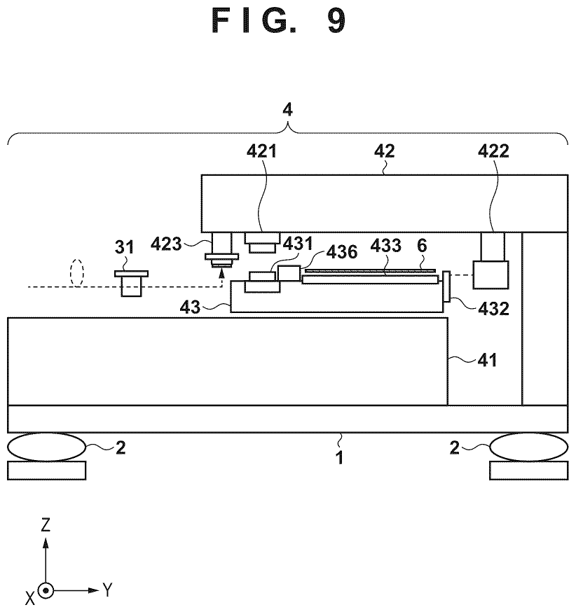

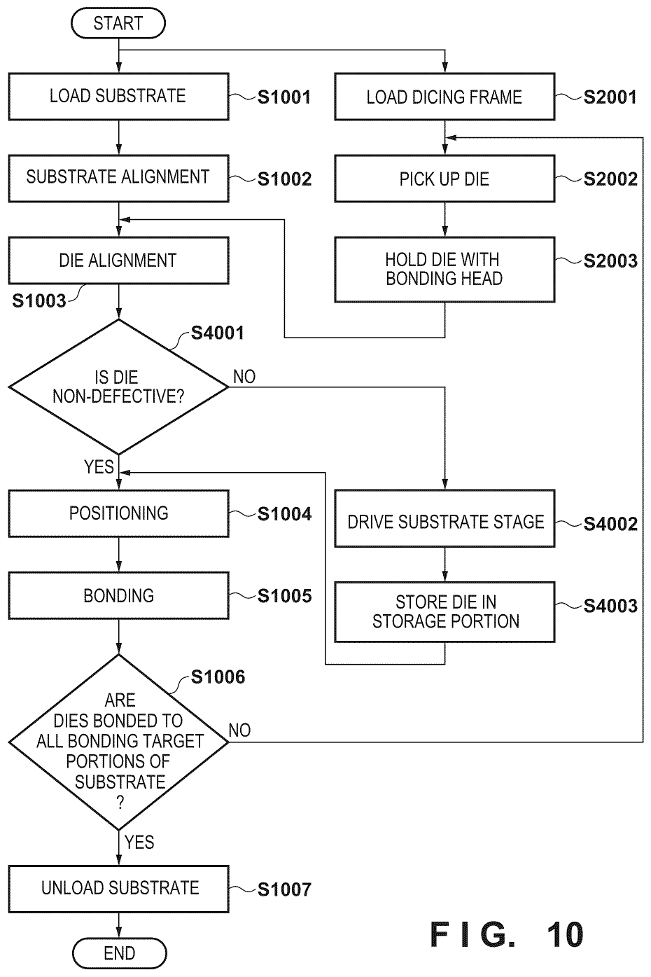

If the state of a bonding surface 51a of a die 51 held by a bonding head 423 is poor, the die 51 needs to be discarded. Therefore, as shown in FIG. 9, a bonding apparatus BD may be provided with a storage portion 436 that receives, from the bonding head 423, and stores the die 51 determined to have the bonding surface 51a in the poor state. FIG. 9 is a view schematically showing the arrangement of a bonding unit 4 of the bonding apparatus BD.

The storage portion 436 has a structure capable of receiving, from the bonding head 423, the die 51 held by the bonding head 423, and is configured to be capable of storing a plurality of dies 51. In this embodiment, the storage portion 436 is provided on a substrate stage 43, but only needs to be provided at a position where it can receive the die 51 from the bonding head 423. Instead of passing the die 51 from the bonding head 423 to the storage portion 436, the die 51 may be passed from the bonding head 423 to the storage portion 436 via a pickup head 31. In this case, the storage portion 436 is provided at a position where it can receive the die 51 from the pickup head 31. The storage portion 436 is fixed to be easily detachable from the bonding apparatus BD, and preferably has a structure detachable while storing the die 51 determined to have the bonding surface 51a in the poor state.

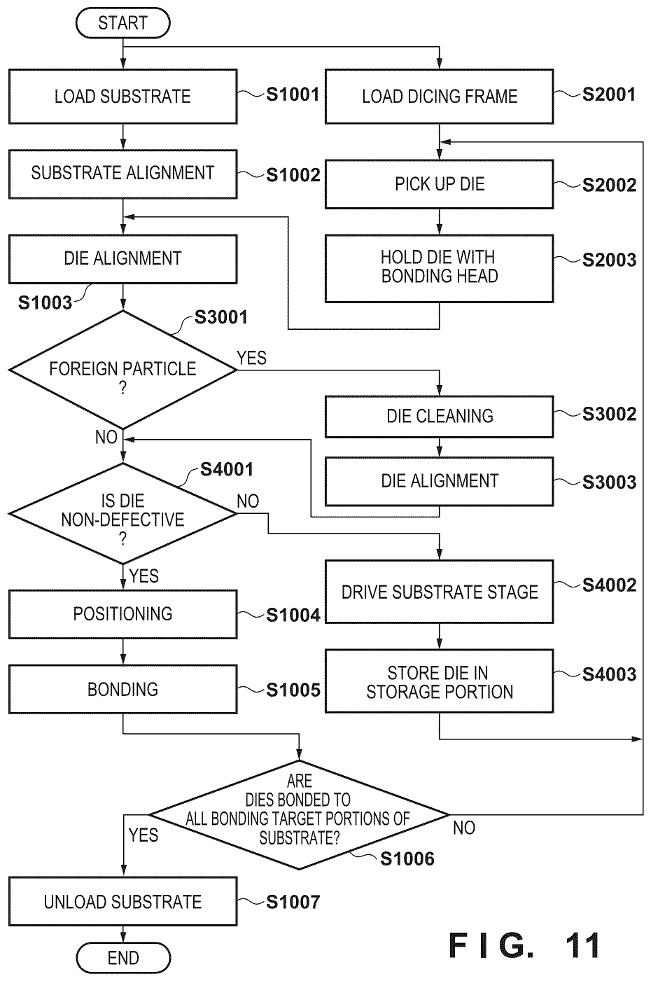

With reference to FIG. 10, an operation of the bonding apparatus BD in the third embodiment, that is, a bonding operation (bonding method) of bonding the die 51 to a substrate 6 will be described. As has been described above, the bonding operation is performed by a control unit CNT comprehensively controlling the respective units of the bonding apparatus BD. The bonding operation in this embodiment is different from the bonding operation (FIG. 3) in the first embodiment in that processing operations in steps S4001, S4002, and S4003 are included between die alignment (step S1003) and positioning (step S1004).

In step S4001, based on the determination (result) of the state of the bonding surface 51a of the die 51 in die alignment (step S1003), it is determined whether the state of the bonding surface 51a of the die 51 is excellent, that is, whether the die 51 is a non-defective die. If the die 51 is a non-defective die, the process transitions to step S1004. On the other hand, if the die 51 is not a non-defective die (that is, if the die 51 is a defective die), the process transitions to step S4002.

In step S4002, the substrate stage 43 is driven to locate the storage portion 436 below the bonding head 423.

In step S4003, the die 51 (defective die) held by the bonding head 423 is passed (transferred) from the bonding head 423 to the storage portion 436 and stored in the storage portion 436.

In this manner, according to this embodiment, it is possible to store, in the storage portion 436, and discard the die 51 determined to be a defective die immediately before bonding the die 51 to the substrate 6. Hence, in this embodiment, it is possible to provide the bonding apparatus BD advantageous in bonding the die 51 to the substrate 6.

### Fourth Embodiment

It is also possible to operate a bonding apparatus BD in combination of the second embodiment and the third embodiment. With reference to FIG. 11, an operation of the bonding apparatus BD in the fourth embodiment, that is, a bonding operation (bonding method) of bonding a die 51 to a substrate 6 will be described. As has been described above, the bonding operation is performed by a control unit CNT comprehensively controlling the respective units of the bonding apparatus BD. The bonding operation in this embodiment is different from the bonding operation (FIG. 3) in the first embodiment in that processing operations in steps S3001, S3002, S3003, S4001, S4002, and S4003 are included between die alignment (step S1003) and positioning (step S1004).

In step S3001, based on the determination (result) of the state of a bonding surface 51a of the die 51 in die alignment (step S1003), it is determined whether there is a foreign particle adhering to the bonding surface 51a of the die 51. If it is determined that there is no foreign particle adhering to the bonding surface 51a of the die 51, the process transitions to step S4001. On the other hand, if there is a foreign particle adhering to the bonding surface 51a of the die 51, the process transitions to step S3002.

In step S3002, cleaning of the bonding surface 51a of the die 51 held by a bonding head 423 is performed.

In step S3003, to determine (check) the state of the bonding surface 51a of the die 51 with the foreign particle removed by a cleaning unit 435, die alignment is performed as in step S1003.

In step S4001, based on the determination (result) of the state of the bonding surface 51a of the die 51 in die alignment (step S1003 or S3003), it is determined whether the state of the bonding surface 51a of the die 51 is excellent, that is, whether the die 51 is a non-defective die. If the die 51 is a non-defective die, the process transitions to step S1004. On the other hand, if the die 51 is not a non-defective die (that is, if the die 51 is a defective die), the process transitions to step S4002.

In step S4002, a substrate stage 43 is driven to locate a storage portion 436 below the bonding head 423.

In step S4003, the die 51 (defective die) held by the bonding head 423 is passed (transferred) from the bonding head 423 to the storage portion 436 and stored in the storage portion 436.

In this manner, according to this embodiment, it is possible to set the excellent state of the bonding surface 51a by removing a foreign particle adhering to the bonding surface 51a of the die 51, if any, immediately before bonding the die 51 to the substrate 6. In addition, it is possible to store, in the storage portion 436, and discard the die 51 determined to be a defective die immediately before bonding the die 51 to the substrate 6. Hence, in this embodiment, it is possible to provide the bonding apparatus BD advantageous in bonding the die 51 to the substrate 6.

Note that, in this embodiment, the processing operations (steps S4001, S4002, and S4003) described in the third embodiment are performed after the processing operations (steps S3001, S3002, and S3003) described in the second embodiment are performed, but the present invention is not limited thereto. For example, the processing operations (steps S3001, S3002, and S3003) described in the second embodiment may be performed after the processing operations (steps S4001, S4002, and S4003) described in the third embodiment are performed.

### Fifth Embodiment

A method of manufacturing an article (a semiconductor IC element, a liquid crystal element, a MEMS, or the like) using the above-described bonding apparatus BD will be described. The article is manufactured by a step of preparing a first object, a step of preparing a second object, a step of forming a bonded object by bonding the first object and the second object using the bonding apparatus BD (bonding method (bonding operation)), and a step of processing the bonded object in another known process. The other known process includes probing, dicing, bonding, packaging, and the like. The article manufacturing method according to this embodiment is advantageous in at least one of the performance, quality, productivity, and production cost of the article, as compared to conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2023-097244 filed on Jun. 13, 2023, which is hereby incorporated by reference herein in its entirety.

What is claimed is:

1. A bonding apparatus that bonds a second object to a first object, comprising:
a head configured to hold the second object and bond the second object to the first object;
a first camera configured to obtain an image by capturing the second object held by the head; and
a control unit configured to determine a state of a bonding surface of the second object on a side of the first object based on an image obtained by the first camera in a state in which the second object is aligned with respect to the head, and control the head not to bond the second object held by the head to the first object if the state of the bonding surface is poor, and to bond the second object held by the head to the first object if the state of the bonding surface is excellent.

2. The apparatus according to claim 1, further comprising a second camera configured to obtain an image by capturing the second object before being held by the head,
wherein the control unit determines the state of the bonding surface by comparing an image obtained by the first camera and an image obtained by the second camera.

3. The apparatus according to claim 2, wherein
the second object is loaded into the apparatus while being held by a tape put on a frame, and
the second camera obtains an image by capturing the second object held by the tape.

4. The apparatus according to claim 1, wherein
the control unit determines the state of the bonding surface by comparing an image captured by the first camera and a reference image obtained by capturing the second object having the bonding surface in an excellent state.

5. The apparatus according to claim 1, wherein
if adhesion of a foreign particle to the bonding surface is detected from an image obtained by the first camera, the control unit determines that the state of the bonding surface is poor.

6. The apparatus according to claim 5, further comprising a cleaning unit configured to perform cleaning for removing a foreign particle adhering to the bonding surface of the second object held by the head.

7. The apparatus according to claim 6, wherein
the cleaning unit is arranged so as to face the bonding surface of the second object held by the head, and removes a foreign particle adhering to the bonding surface by blowing air to the bonding surface.

8. The apparatus according to claim 1, wherein
if one of chipping of an outer shape of the bonding surface, a positional deviation of a pattern formed in the bonding surface, chipping of a pattern formed in the bonding surface, and adhesion of a foreign particle to the bonding surface is detected from an image obtained by the first camera, the control unit determines that the state of the bonding surface is poor.

9. The apparatus according to claim 1, further comprising a storage portion configured to receive, from the head, and store the second object determined to have the bonding surface in a poor state by the control unit.

10. A bonding apparatus that bonds a second object to a first object, comprising:
a head configured to hold the second object and bond the second object to the first object;
a camera configured to obtain an image by capturing the second object held by the head; and
a control unit configured to obtain, from an image obtained by the camera, an alignment amount required for alignment of the second object with respect to the head, determine a state of a bonding surface of the second object on a side of the first object based on a result obtained by performing image processing of the image based on the alignment amount, and control the head not to bond the second object held by the head to the first object if the state of the bonding surface is poor, and to bond the second object held by the head to the first object if the state of the bonding surface is excellent.

11. A bonding method of bonding a second object to a first object, comprising:
obtaining an image by capturing the second object held by a head configured to bond the second object to the first object; and
determining a state of a bonding surface of the second object on a side of the first object based on an image obtained in the obtaining in a state in which the second object is aligned with respect to the head, and controlling the head not to bond the second object held by the head to the first object if the state of the bonding surface is poor, and to bond the second object held by the head to the first object if the state of the bonding surface is excellent.

12. A bonding method of bonding a second object to a first object, comprising:
obtaining an image by capturing the second object held by a head configured to bond the second object to the first object; and
obtaining, from an image obtained in the obtaining, an alignment amount required for alignment of the second object with respect to the head, determining a state of a bonding surface of the second object on a side of the first object based on a result obtained by performing image processing of the image based on the alignment amount, and controlling the head not to bond the second object held by the head to the first object if the state of the bonding surface is poor, and to bond the second object held by the head to the first object if the state of the bonding surface is excellent.

13. An article manufacturing method comprising:
preparing a first object;
preparing a second object;
forming a bonded object by bonding the second object to the first object in accordance with a bonding method defined in claim 11; and
processing the bonded object to manufacture an article.

14. An article manufacturing method comprising:
preparing a first object;
preparing a second object;
forming a bonded object by bonding the second object to the first object in accordance with a bonding method defined in claim 12; and
processing the bonded object to manufacture an article.
